(19) United States
(12) Patent Application Publication
(10) Pub. No.: US 2015/0287763 A1
(43) Pub. Date: Oct. 8, 2015

(54) PIXEL ARRAY

(71) Applicant: E Ink Holdings Inc., Hsinchu (TW)

(72) Inventors: Pei-Lin Huang, Hsinchu (TW); Po-Yuan Lo, Hsinchu (TW); Yu-Nan Pao, Hsinchu (TW); Ya-Wen Lin, Hsinchu (TW)

(21) Appl. No.: 14/596,225

(22) Filed: Jan. 14, 2015

(30) Foreign Application Priority Data
Apr. 7, 2014 (TW) 103112723

(51) Int. Cl. H01L 27/15; H01L 33/50

(52) U.S. Cl. CPC H01L 27/156; H01L 33/50

(57) ABSTRACT

A pixel array includes a substrate and color filter patterns. The substrate has pixel areas. Each of the pixel areas has a first sub-pixel region, a second sub-pixel region, a third sub-pixel region and a fourth sub-pixel region. The first, the second, the third and the fourth sub-pixel regions are arranged sequentially in the clockwise direction. The color filter patterns are disposed on the pixel areas of the substrate and located in the first, the second, the third and the fourth sub-pixel regions. The color filter patterns located in the first, the second, the third and the fourth sub-pixel regions of each of the pixel areas respectively have different colors. The color filter patterns respectively disposed in four adjacent pixel areas and located in the first, the second, the third and the fourth sub-pixel regions adjacent to each other and arranged in the clockwise direction have the same color.

### CROSS-REFERENCE TO RELATED APPLICATION

This application claims the priority benefit of Taiwan application serial no. 103112723, filed on Apr. 7, 2014. The entirety of the above-mentioned patent application is hereby incorporated by reference herein and made a part of this specification.

### BACKGROUND OF THE INVENTION

1. Field of the Invention

The invention generally relates to a display array, and more particularly, to a pixel array.

2. Description of Related Art

In the conventional pixel array, each pixel area is driven by an active element, and only one color filter pattern is disposed in each pixel area. In general, color saturation of display screen is mostly modified by means of increasing the size of the pixel area so as to satisfy the current color saturation demands of the display screen. However, the aforementioned approach trends to lower the resolutions of the display screen under a same size, and thereby cause a display effect of the display screen to become poor.

### SUMMARY OF THE INVENTION

The invention is directed to a pixel array capable of enhancing a screen resolution of a display device that adopts this pixel array, so as to provide favorable display effect to a display screen.

The pixel array of the invention includes a substrate and a plurality of color filter patterns. The substrate has a plurality of pixel areas. Each of the pixel areas has a first sub-pixel region, a second sub-pixel region, a third sub-pixel region and a fourth sub-pixel region, and the first sub-pixel region, the second sub-pixel region, the third sub-pixel region and the fourth sub-pixel region are arranged sequentially in a clockwise direction. The color filter patterns are disposed in the pixel areas of the substrate and located within the first sub-pixel regions, the second sub-pixel regions, the third sub-pixel regions and the fourth sub-pixel regions. The color filter patterns located within the first sub-pixel region, the second sub-pixel region, the third sub-pixel region and the fourth sub-pixel region of each of the pixel areas respectively have different colors. The color filter patterns respectively disposed in the four adjacent pixel areas and located within one of the first sub-pixel region, one of the second sub-pixel region, one of the third sub-pixel region and one of the fourth sub-pixel region that are adjacent to each other and arranged in the clockwise direction have the same color.

In an embodiment of the invention, the pixel areas are arranged into a matrix pattern.

In an embodiment of the invention, the first sub-pixel region, the second sub-pixel region, the third sub-pixel region and the fourth sub-pixel region of each of the pixel areas are arranged into a square.

In an embodiment of the invention, the color filter patterns include a plurality of first color filter patterns, a plurality of second color filter patterns, a plurality of third color filter patterns and a plurality of fourth color filter patterns.

In an embodiment of the invention, the first color filter patterns are a plurality of red color filter patterns.

In an embodiment of the invention, the second color filter patterns are a plurality of green color filter patterns.

In an embodiment of the invention, the third color filter patterns are a plurality of blue color filter patterns.

In an embodiment of the invention, the fourth color filter patterns are a plurality of white color filter patterns.

In view of above, in the pixel array of the invention, the color filter patterns located within the first sub-pixel region, the second sub-pixel region, the third sub-pixel region and the fourth sub-pixel region of each of the pixel areas respectively have different colors, and the color filter patterns respectively disposed in the four adjacent pixel areas and located within the first sub-pixel region, the second sub-pixel region, the third sub-pixel region and the fourth sub-pixel region adjacent to each other and arranged in the clockwise direction have the same color. As a result, the design of the pixel array of the invention may effectively enhance the screen resolution of the display device that adopts this pixel array, so that the display screen may have favorable display effect.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view illustrating a pixel array according to an embodiment of the invention.

### DESCRIPTION OF THE EMBODIMENTS

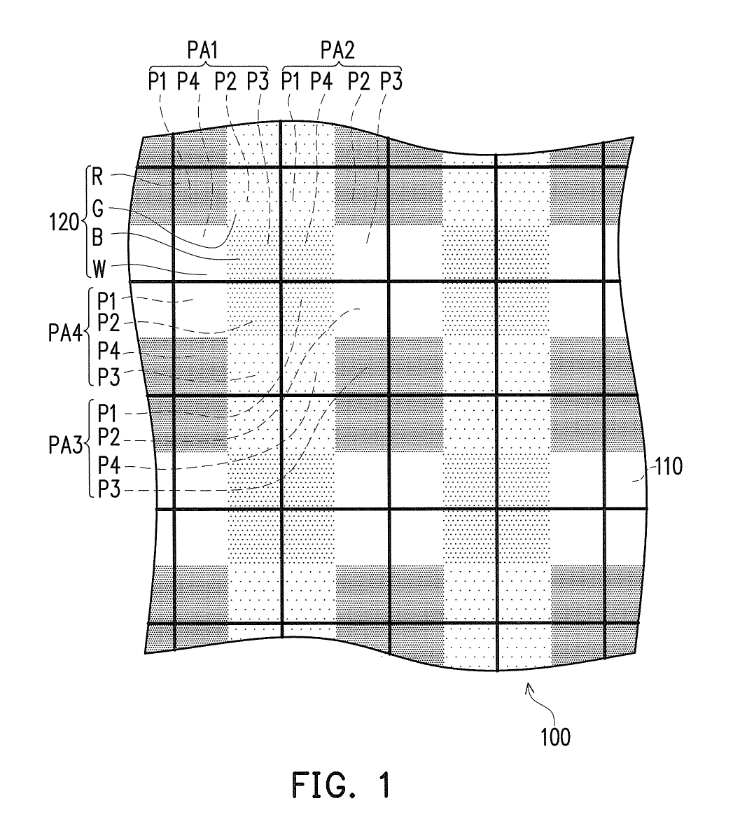

FIG. 1 is a schematic top view illustrating a pixel array according to an embodiment of the invention. Referring to FIG. 1, in the present embodiment, a pixel array 100 includes a substrate 110 and a plurality of color filter patterns 120. The substrate 110 has a plurality of pixel areas PA1, PA2, PA3, PA4. Each of the pixel areas PA1 (or, the pixel areas PA2, PA3, PA4) has a first sub-pixel region P1, a second sub-pixel region P2, a third sub-pixel region P3 and a fourth sub-pixel region P4, and the first sub-pixel region P1, the second sub-pixel region P2, the third sub-pixel region P3 and the fourth sub-pixel region P4 are arranged sequentially in a clockwise direction. Herein, as shown in FIG. 1, the pixel areas PA1, PA2, PA3, PA4 of the invention are substantially arranged into a matrix pattern, and the first sub-pixel region P1, the second sub-pixel region P2, the third sub-pixel region P3 and the fourth sub-pixel region P4 of each of the pixel areas PA1 (or, the pixel areas PA2, PA3, PA4) are substantially arranged into a square, whereby each of the pixel areas PA1 (or, the pixel areas PA2, PA3, PA4) is driven by an active element (not shown).

The color filter patterns 120 are disposed in the pixel areas PA1, PA2, PA3, PA4 of the substrate 110 and located within the first sub-pixel regions P1, the second sub-pixel regions P2, the third sub-pixel regions P3 and the fourth sub-pixel regions P4. Particularly, the color filter patterns 120 located within the first sub-pixel region P1, the second sub-pixel region P2, the third sub-pixel region P3 and the fourth sub-pixel region P4 of each of the pixel areas PA1 (or, the pixel areas PA2, PA3, PA4) respectively have different colors. The color filter patterns 120 respectively disposed in the four adjacent pixel areas PA1, PA2, PA3, PA4 and located within one of the first sub-pixel regions P1, one of the second sub-pixel regions P2, one of the third sub-pixel regions P3 and one of the fourth sub-pixel regions P4 that are adjacent to each other and arranged in the clockwise direction have the same color.

To be more specific, the color filter patterns 120 of the present embodiment include a plurality of first color filter patterns R, a plurality of second color filter patterns G, a plurality of third color filter patterns B and a plurality of fourth color filter patterns W, wherein the first color filter patterns R, for example, are a plurality of red color filter patterns, the second color filter patterns G for example, are a plurality of green color filter patterns, the third color filter patterns B for example, are a plurality of blue color filter patterns, and the fourth color filter patterns W for example, are a plurality of white color filter patterns. As shown in FIG. 1, each of the pixel areas PA1 (or, the pixel areas PA2, PA3, PA4) respectively has one first color filter pattern R, one second color filter pattern G, one third color filter pattern B and one fourth color filter pattern W therein. Whereas, the third sub-pixel region P3 in the pixel areas PA1, the fourth sub-pixel region P4 in the pixel areas PA2, the first sub-pixel region P1 in the pixel areas PA3 and the second sub-pixel region P2 in the pixel areas PA4 are adjacent to each other and arranged in the clockwise direction. And, the color filter patterns 120 located within the third sub-pixel region P3 of the pixel areas PA1, the fourth sub-pixel region P4 of the pixel areas PA2, the first sub-pixel region P1 of the pixel areas PA3 and the second sub-pixel region P2 of the pixel areas PA4 have the same color, such as the first color filter patterns R (viz. the red color filter patterns), the second color filter patterns G (viz. the green color filter patterns), the third color filter patterns B (viz. the blue color filter patterns) or the fourth color filter patterns W (viz. the white color filter patterns).

In other words, each of the pixel areas PA1 (or, the pixel areas PA2, PA3, PA4) of the present embodiment has four different colors of color filter patterns 120 therein, and the color filter patterns 120 within the first sub-pixel region P1, the second sub-pixel region P2, the third sub-pixel region P3 and the fourth sub-pixel region P4, that are adjacent to each other and arranged in the clockwise direction, in the four adjacent pixel areas PA1, PA2, PA3, PA4 may have the same color. Namely, a color block constituted of four color filter patterns 120 having the same color can driven by 2×2 active elements (not shown). Therefore, unlike from the conventional art, the present embodiment does not have to enhance a display effect of the a display screen by increasing the size of the pixel areas, and may directly enhance a screen resolution of a display device (not shown) using the pixel array 100 with the above-described design, so that the display screen may have favorable color saturation, thereby providing the display screen with favorable display quality.

In summary, in the pixel array of the invention, the color filter patterns located within the first sub-pixel region, the second sub-pixel region, the third sub-pixel region and the fourth sub-pixel region of each of the pixel areas respectively have different colors, and the color filter patterns respectively disposed in the four adjacent pixel areas and located within the first sub-pixel region, the second sub-pixel region, the third sub-pixel region and the fourth sub-pixel region adjacent to each other and arranged in the clockwise direction have the same color. As a result, the design of the pixel array of the invention may effectively enhance the screen resolution of the display device that adopts this pixel array, so that the display screen may have favorable display effect.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pixel array, comprising:
a substrate having a plurality of pixel areas, wherein each of the pixel areas has a first sub-pixel region, a second sub-pixel region, a third sub-pixel region and a fourth sub-pixel region, and the first sub-pixel region, the second sub-pixel region, the third sub-pixel region and the fourth sub-pixel region are arranged sequentially in a clockwise direction; and
a plurality of color filter patterns disposed in the pixel areas of the substrate and located within the first sub-pixel regions, the second sub-pixel regions, the third sub-pixel regions and the fourth sub-pixel regions, wherein the color filter patterns located within the first sub-pixel region, the second sub-pixel region, the third sub-pixel region and the fourth sub-pixel region of each of the pixel areas respectively have different colors, and the color filter patterns respectively disposed in four adjacent pixel areas and located within one of the first sub-pixel regions, one of the second sub-pixel regions, one of the third sub-pixel region and one of the fourth sub-pixel region adjacent to each other and arranged in the clockwise direction have the same color.

2. The pixel array as recited in claim 1, wherein the pixel areas are arranged into a matrix pattern.

3. The pixel array as recited in claim 1, wherein the first sub-pixel region, the second sub-pixel region, the third sub-pixel region and the fourth sub-pixel region of each of the pixel areas are arranged into a square.

4. The pixel array as recited in claim 1, wherein the color filter patterns comprise a plurality of first color filter patterns, a plurality of second color filter patterns, a plurality of third color filter patterns and a plurality of fourth color filter patterns.

5. The pixel array as recited in claim 4, wherein the first color filter patterns are a plurality of red color filter patterns.

6. The pixel array as recited in claim 4, wherein the second color filter patterns are a plurality of green color filter patterns.

7. The pixel array as recited in claim 4, wherein the third color filter patterns are a plurality of blue color filter patterns.

8. The pixel array as recited in claim 4, wherein the fourth color filter patterns are a plurality of white color filter patterns.
